(19) United States
(12) Patent Application Publication
(10) Pub. No.: US 2026/0130259 A1
(43) Pub. Date: May 7, 2026

(54) SEMICONDUCTOR DEVICE

(71) Applicant: FUJI ELECTRIC CO., LTD., Kawasaki-shi (JP)

(72) Inventors: Naoyuki KANAI, Matsumoto-city (JP); Ryoichi Kato, Matsumoto-city (JP)

(73) Assignee: FUJI ELECTRIC CO., LTD., Kawasaki-shi (JP)

(21) Appl. No.: 19/440,169

(22) Filed: Jan. 5, 2026

Related U.S. Application Data
(63) Continuation of application No. PCT/JP2024/045840, filed on Dec. 25, 2024.

(30) Foreign Application Priority Data
Mar. 11, 2024 (JP) 2024-037394

(51) Int. Cl. H10W 72/60; H10D 80/20; H10W 40/25; H10W 74/10; H10W 90/00; H10W 90/10

(52) U.S. Cl. CPC H10W 72/622; H10D 80/251; H10W 40/255; H10W 74/114; H10W 90/10; H10W 90/764

(57) ABSTRACT

Provided is a semiconductor device with a configuration capable of ensuring insulation properties between terminals having different potentials and arranged with an insulating layer interposed. The semiconductor device includes: a first terminal; a second terminal having a part opposed to the first terminal and another part provided with a first opening not opposed to the first terminal; and an insulating layer including a body part interposed between the first terminal and the second terminal opposed to each other and a first protrusion connected to the body part and inserted to the first opening.

### CROSS-REFERENCE TO RELATED APPLICATION

This application is a Continuation of PCT Application No. PCT/JP2024/045840, filed on Dec. 25, 2024, and claims the priority of Japanese Patent Application No. 2024-037394, filed on Mar. 11, 2024, the content of which are incorporated herein by reference.

### TECHNICAL FIELD

The present invention relates to semiconductor devices (power semiconductor modules).

### BACKGROUND ART

JP2010-157565A discloses a configuration including three electrode-leading terminals stacked together with insulating resin sheets interposed so as to implement a five-layer structure, in which positioning pins are inserted to two stacking holes provided in the five-layer structure so as to achieve mutual positioning between the respective layers.

JP2023-088055A discloses a configuration including an insulating sheet having a first main surface and a second main surface, a first terminal in a shape of a plate provided to face the first main surface of the insulating sheet and including a first protruding portion protruding outward from the first main surface of the insulating sheet, and a second terminal in a shape of a plate provided to face the second main surface of the insulating sheet and including a second protruding portion protruding outward from the second main surface of the insulating sheet side by side with the first protruding portion, wherein a first recessed opening portion is provided at a position of the first protruding portion intersecting an end portion of the insulating sheet by concaving a side surface of the first protruding portion facing the second protruding portion in a direction away from the second protruding portion.

JP2019-207922A discloses a configuration including main terminals having projecting portions projecting outward from a sealing resin body, the projecting portions having facing portions provided with plate surfaces arranged separately to face each other so as to mutually cancel out magnetic fluxes caused during a flow of main currents and having non-facing portions at which the respective plate surfaces do not face each other.

JP2006-086438A discloses a configuration including a metal die for resin molding preliminarily provided with positioning pins, wherein the guide holes in the insulating sheet are formed to have a sufficiently smaller size than those in respective plus and minus busbars, while the positioning pins are provided with steps conforming to the corresponding sizes of the diameters of the respective guide holes, so as to increase the accuracy of positioning when the positioning pins are sequentially inserted into the respective guide holes of the plus busbar, the insulating sheet, and the minus busbar.

JP2005-065414A discloses a configuration including a positive-electrode conductor, an insulating sheet, and a negative-electrode conductor laminated together, and including insulating caps arranged between the positive-electrode conductor and the insulating sheet, each insulating cap provided with a flange for ensuring a creepage distance and barrier parts for ensuring a space distance, wherein the positive-electrode conductor is provided with holes having a size set only necessary for the insertion of the barrier parts of the insulating caps, and the negative-electrode conductor is provided with holes having a size set only necessary for the penetration and positioning of the barrier parts, so as to greatly enhance the effect of reducing inductance obtained by proximity of opposing currents.

### SUMMARY OF THE INVENTION

### Technical Problem

Conventional power semiconductor devices developed recently have a configuration in which terminals having different potentials are arranged to be opposed to each other (laminated together) with an insulating layer interposed in order to achieve a reduction in inductance.

Such a configuration, however, has a problem of not easy positioning between the respective terminals and the insulating layer, which impedes the effect of ensuring the insulation properties between the respective terminals.

In view of the foregoing problems, the present disclosure provides a semiconductor device having a configuration capable of ensuring insulation properties between terminals having different potentials stacked together with an insulating layer interposed.

### Solution to Problem

An aspect of the present disclosure inheres in a semiconductor device including: a first terminal; a second terminal having a part opposed to the first terminal and another part provided with a first opening not opposed to the first terminal; and an insulating layer including a body part interposed between the first terminal and the second terminal opposed to each other, and a first protrusion connected to the body part and inserted to the first opening.

In the aspect of the present disclosure, the second terminal may include: a first flat part having at least a part opposed to the first terminal; and a first connection part bent from the first flat part so as to be connected to each other.

In the aspect of the present disclosure, the first opening may be provided in the first connection part.

In the aspect of the present disclosure, a part of the first flat part may be opposed to the first terminal, and another part of the first flat part not opposed to the first terminal may be provided with the first opening; and the first protrusion may be bent from the body part so as to be inserted to the first opening.

In the aspect of the present disclosure, the second terminal may further include a second connection part bent from the first flat part so as to be connected to each other on an opposite side of the first connection part, and provided with a second opening, and the insulating layer may further include a second protrusion connected to the body part and inserted to the second opening.

In the aspect of the present disclosure, a part of the first terminal may be opposed to the second terminal, and another part of the first terminal not opposed to the second terminal is provided with a second opening, and the insulating layer may further include a second protrusion connected to the body part and inserted to the second opening.

In the aspect of the present disclosure, the first terminal may include: a second flat part having at least a part opposed to the second terminal; and a third connection part bent from the second flat part so as to be connected to each other.

In the aspect of the present disclosure, the third connection part may be provided with the second opening.

In the aspect of the present disclosure, a part of the second flat part may be opposed to the second terminal, and another part of the second flat part is provided with the second opening, and the second protrusion may be bent so as to be inserted to the second opening.

In the aspect of the present disclosure, the first protrusion and the second protrusion may be located so as to be opposed to each other with the body part interposed.

In the aspect of the present disclosure, the first protrusion and the second protrusion may be shifted from each other so as not to be opposed to each other with the body part interposed.

In the aspect of the present disclosure, the first protrusion may be provided with a catch part.

In the aspect of the present disclosure, a tip part of the first protrusion may project from the first opening and is further bent.

In the aspect of the present disclosure, a length of the first protrusion may be greater than or equal to a thickness of the second terminal.

In the aspect of the present disclosure, the semiconductor device may further include: an insulated circuit substrate provided with the first terminal and the second terminal on a top surface side; a semiconductor chip provided on the top surface side of the insulated circuit substrate and electrically connected to the first terminal and the second terminal; and a sealing resin provided to seal the insulated circuit substrate and the semiconductor chip.

It should be noted that the above summary of the invention does not list all the necessary features of the present disclosure. Subcombinations of these feature groups can also be inventions.

### BRIEF DESCRIPTION OF THE DRAWINGS

FIG. 1 is a side view illustrating a semiconductor device according to a first embodiment;

FIG. 2 is a plan view illustrating components included in the semiconductor device according to the first embodiment;

FIG. 3A is a cross-sectional view taken along line A-A′ in FIG. 2;

FIG. 3B is a cross-sectional view taken along line B-B′ in FIG. 2;

FIG. 4 is a side view illustrating the components included in the semiconductor device according to the first embodiment;

FIG. 5 is a side view illustrating the components included in the semiconductor device according to the first embodiment;

FIG. 6 is a plan view illustrating the components included in the semiconductor device according to the first embodiment;

FIG. 7 is a plan view illustrating the components included in the semiconductor device according to the first embodiment;

FIG. 8 is a plan view illustrating components included in a semiconductor device according to a second embodiment;

FIG. 9 is a plan view illustrating components included in a semiconductor device according to a third embodiment;

FIG. 10A is a plan view illustrating components included in a semiconductor device according to a fourth embodiment;

FIG. 10B is a plan view illustrating the components included in the semiconductor device according to the fourth embodiment;

FIG. 11 is a cross-sectional view illustrating components included in a semiconductor device according to a fifth embodiment;

FIG. 12A is a cross-sectional view illustrating components included in a semiconductor device according to a sixth embodiment;

FIG. 12B is a cross-sectional view taken along line B-B′ in FIG. 12A;

FIG. 13 is a cross-sectional view illustrating components included in a semiconductor device according to a seventh embodiment;

FIG. 14 is a plan view illustrating components included in a semiconductor device according to an eighth embodiment;

FIG. 15 is a cross-sectional view taken along line A-A′ in FIG. 14;

FIG. 16 is a cross-sectional view taken along line B-B′ in FIG. 14;

FIG. 17 is a side view illustrating the components included in the semiconductor device according to the eighth embodiment;

FIG. 18 is a plan view illustrating components included in a semiconductor device according to a ninth embodiment;

FIG. 19 is a plan view illustrating components included in a semiconductor device according to a tenth embodiment;

FIG. 20 is a plan view illustrating components included in a semiconductor device according to an eleventh embodiment; and

FIG. 21 is a cross-sectional view taken along line B-B′ in FIG. 20.

### DETAILED DESCRIPTION

Hereinafter, first to eleventh embodiments of the present disclosure are described with reference to the drawings.

In the following descriptions of the drawings, the same or similar components are denoted by the same or similar reference numerals. It should be understood that the drawings are schematic illustrations, and the relations between thicknesses and planar dimensions, or proportions of thicknesses of layers illustrated below are not drawn to scale. The specific thicknesses or dimensions of the components thus should be referred to as appropriate in accordance with the corresponding explanations as made below. It should also be understood that the relations or proportions of the dimensions between the respective drawings can differ from each other.

In the following descriptions, the directional definitions such as “top”, “bottom”, “upper-lower”, “left”, “right”, and “right-left” are made simply for illustration purposes, and are not intended to limit the technical ideas of the present disclosure. For example, when a direction of a target is turned by 90 degrees and is observed, the term “upper-lower” should be changed to the term “right-left”, and when the direction of the target is turned by 180 degrees, the term “upper-lower” should be reversed.

In addition, the terms “top surface” and “bottom surface” in the following descriptions may be changed to the terms “front surface” and “rear surface”. Further, the terms “first main surface” and “second main surface” used for the components described below refer to main surfaces opposed to each other. For example, when the “first main surface” is defined as a top surface, the “second main surface” is then defined as a bottom surface. Further, the “first main surface” and the “second main surface” as used herein can also be referred to “one of main surfaces” and “the other main surface” respectively.

### First Embodiment

### Configuration of Semiconductor Device

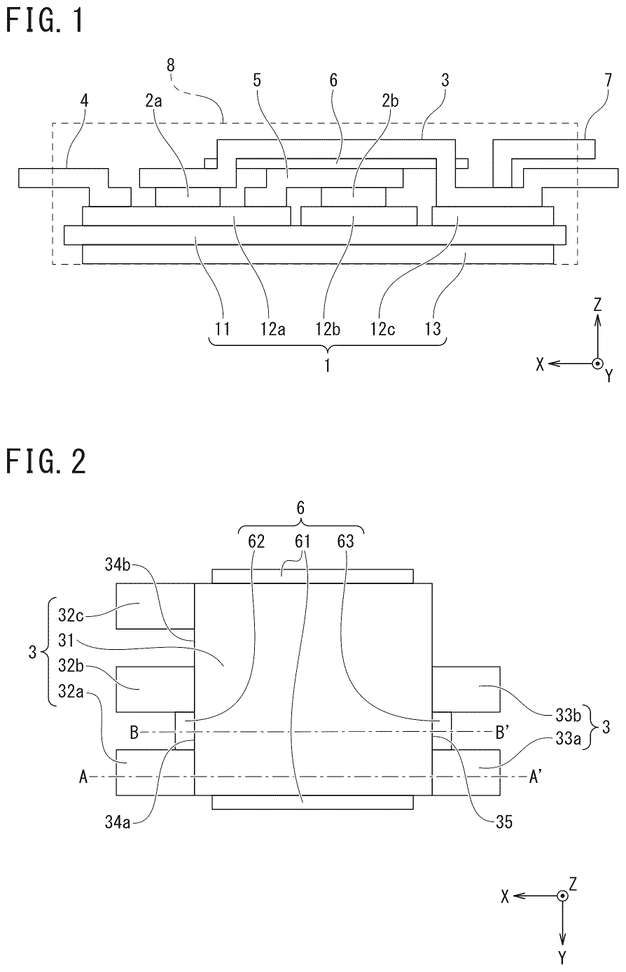

A semiconductor device according to a first embodiment may be a “2-in-1” power semiconductor module implementing a part of a three-phase bridge circuit and having functions for two power semiconductor elements. FIG. 1 is a side view illustrating the semiconductor device according to the first embodiment. FIG. 1 defines the right-left direction as an X-axis direction, and defines the left direction as a positive direction of the X-axis. FIG. 1 also defines the frontward-rearward direction perpendicular to the X-axis direction in FIG. 1 as a Y-axis direction, and defines the frontward direction as a positive direction of the Y-axis. FIG. 1 also defines the upper-lower direction perpendicular to the X-axis direction and the Y-axis direction as a Z-axis direction, and defines the upper direction as a positive direction of the Z-axis. The same directional definitions are also applied to the explanations of the drawings other than FIG. 1.

As illustrated in FIG. 1, the semiconductor device according to the first embodiment includes an insulated circuit substrate 1, power semiconductor elements (semiconductor chips) 2a and 2b arranged on the top surface side of the insulated circuit substrate 1, and terminals 3 to 5 and 7 arranged on the top surface side of the insulated circuit substrate 1 so as to be electrically connected to the semiconductor chips 2a and 2b.

The insulated circuit substrate 1 may be a direct copper bonded (DCB) substrate or an active metal brazed (AMB) substrate, for example. The insulated circuit substrate 1 includes an insulating plate 11, conductive plates 12a to 12c provided on the top surface side of the insulating plate 11, and a conductive plate 13 provided on the bottom surface side of the insulating plate 11. The insulating plate 11 is a resin insulating layer including polymer material, or a ceramic plate mainly including aluminum oxide (Al₂O₃), aluminum nitride (AlN), silicon nitride (Si₃N₄), or boron nitride (BN), for example. The conductive plates 12a to 12c and the conductive plate 13 each include conductive material such as copper (Cu), a Cu alloy, aluminum (Al), and an Al alloy, for example. The arranged positions and the number of the conductive plates 12a to 12c may be changed as appropriate.

The semiconductor chips 2a and 2b are each implemented by a semiconductor substrate including silicon (Si), silicon carbide (SiC), gallium nitride (GaN), gallium oxide (Ga₂O₃), or diamond (C), for example. The respective semiconductor chips 2a and 2b may be a field-effect transistor (FET) such as a metal-oxide semiconductor field-effect transistor (MOSFET), an insulated gate bipolar transistor (IGBT), a static induction (SI) thyristor, or a gate turn-off (GTO) thyristor, for example. The type, the arranged positions, and the number of the semiconductor chips 2a and 2b may be changed as appropriate. The semiconductor device according to the first embodiment is illustrated below with a case in which the semiconductor chips 2a and 2b are each a MOSFET.

A first electrode (a drain electrode) (not illustrated) on the bottom surface side of the semiconductor chip 2a is bonded to the top surface of the conductive plate 12a of the insulated circuit substrate 1 via bonding material such as solder and sintering material. A first electrode (a drain electrode) (not illustrated) on the bottom surface side of the semiconductor chip 2b is bonded to the top surface of the conductive plate 12b of the insulated circuit substrate 1 via bonding material such as solder and sintering material.

The respective terminals 3 to 5 and 7 include conductive material such as copper (Cu), a Cu alloy, aluminum (Al), and an Al alloy, for example. The terminals 3 to 5 and 7 each have a plate-like shape having a first main surface (a top surface) and a second main surface (a bottom surface). The arranged positions, the lengths, the widths, and the thicknesses of the terminals 3 to 5 and 7 may be changed as appropriate. The position and the number of bent parts provided in the respective terminals 3 to 5 and 7 may be determined as appropriate.

One end of the terminal 7, which is hidden on the rearward side of the terminal 3, is bonded to another conductive plate (not illustrated) having a potential common to that of the conductive plate 12a or 12b of the insulated circuit substrate 1 via bonding material (not illustrated) such as solder and sintering material. The other end of the terminal 7 extends to the outside of the outer edge of the insulated circuit substrate 1. The terminal 7 may serve as a positive-electrode terminal which is an external connection terminal, for example.

One end of the terminal 4 is bonded to the top surface of the conductive plate 12a of the insulated circuit substrate 1 via bonding material (not illustrated) such as solder and sintering material. The other end of the terminal 4 extends to the outside of the outer edge of the insulated circuit substrate 1. The terminal 4 may serve as an output terminal which is an external connection terminal, for example.

One end of the terminal 5 is bonded to the top surface of the conductive plate 12a of the insulated circuit substrate 1 via bonding material (not illustrated) such as solder and sintering material. The other end of the terminal 5 is bonded to a second electrode (a source electrode) (not illustrated) on the top surface side of the semiconductor chip 2b via bonding material (not illustrated) such as solder and sintering material. The illustrations of terminals, bonding wires, or the like connected to a third electrode (a gate electrode) on the top surface side of the respective semiconductor chips 2a and 2b are omitted.

One end of the terminal 3 is bonded to a second electrode (a source electrode) (not illustrated) on the top surface side of the semiconductor chip 2a via bonding material (not illustrated) such as solder and sintering material. The other end of the terminal 3 is bonded to the top surface of the conductive plate 12c of the insulated circuit substrate 1 via bonding material (not illustrated) such as solder and sintering material, and further extends to the outside of the outer edge of the insulated circuit substrate 1. The terminal 3 may serve as a negative-electrode terminal which is an external connection terminal, for example.

The bottom surface in the middle of the terminal 3 is opposed to the top surface of the terminal 5 with the insulating layer 6 interposed. In particular, the terminal 3 and the terminal 5 are opposed and arranged adjacent to each other (laminated together) with the insulating layer 6 interposed. The terminal 3 and the terminal 5 are terminals (different-electrode terminals) to which potentials different from each other are applied. During ON/OFF operations of the respective semiconductor chips 2a and 2b, currents flow through the terminal 3 and the terminal 5 in the opposite directions, so as to reduce wiring inductance due to mutual inductance in a part at which the terminal 3 and the terminal 5 are opposed to each other (at the opposed part). Since the wiring inductance between the different-electrode terminals inside the power semiconductor module has an influence on a switching loss, it is important to decrease an inductance value. Particularly since devices including SiC, GaN, and the like enable rapid switching, a reduction in inductance is quire necessary for the power semiconductor module. The arrangement (lamination) of the different-electrode terminals adjacent to each other inside the power semiconductor module is effective for the reduction in inductance.

The insulating layer 6 is a sheet-like insulating member (an insulating sheet), for example. The insulating layer 6 as used herein can be an insulating sheet or include insulating material having high insulation and heat-resistance properties such as polyimide and polyamide, or may include epoxy resin or polyphenylene sulfide (PPS) resin instead. A thickness of the insulating layer 6 is set in a range of about 0.1 millimeters or greater and 1.5 millimeters or smaller, for example, but is not limited to this range. The thickness of the insulating layer 6 is preferably set in a range of about 0.1 millimeters or greater and 1.0 millimeters or smaller, and more preferably set in a range of about 0.1 millimeters or greater and 0.5 millimeters or smaller, for example, in view of a reduction in inductance. The thickness of the insulating layer 6 conforms to the distance between the terminal 3 and the terminal 5 opposed to each other. As the thickness of the insulating layer 6 is thinner, the distance between the terminal 3 and the terminal 5 is smaller, so as to reduce the wiring inductance.

As schematically indicated by the broken line in FIG. 1, a sealing resin 8 is provided to seal the insulated circuit substrate 1, the semiconductor chips 2a and 2b, and the like. The sealing resin 8 is resin material such as epoxy resin, for example. The sealing resin 8 may be formed by transfer molding with no case used. Alternatively, the sealing resin 8 may include a resin-based case, and resin filled inside the case by potting. The outline of the sealing resin 8 is not limited to the substantially cuboidal shape, and may be any other solid shapes.

The bottom surface of the insulated circuit substrate 1 is exposed on the bottom surface of the sealing resin 8. The respective terminals 3 and 7 project from the common side surface of the sealing resin 8 to further extend in one direction. The terminal 4 projects from the side surface on the opposite side of the side surface from which the terminals 3 and 7 project so as to further extend in the opposite direction. The terminals 3, 4, and 7 may each be provided with a bent portion in the projecting part out of the sealing resin 8. At least one of the terminals 3, 4, and 7 may project from the top surface of the sealing resin 8.

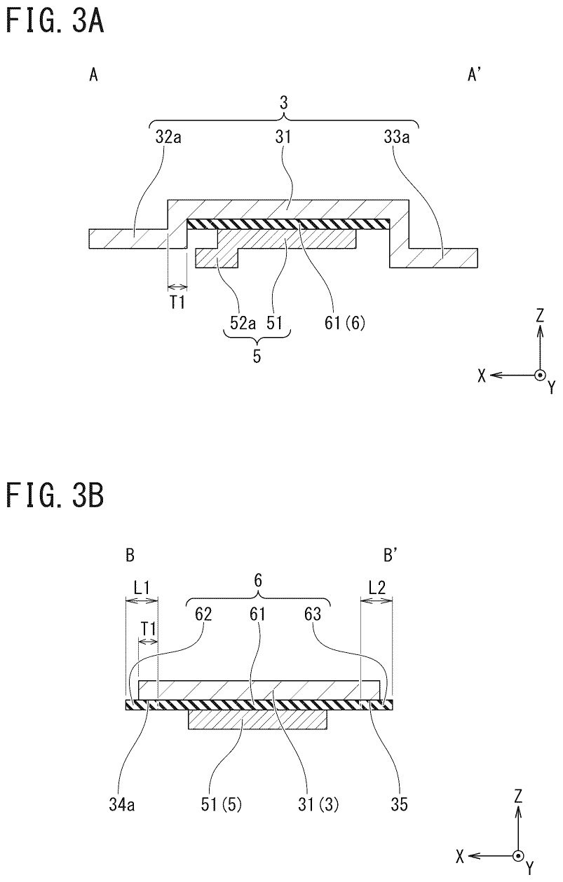

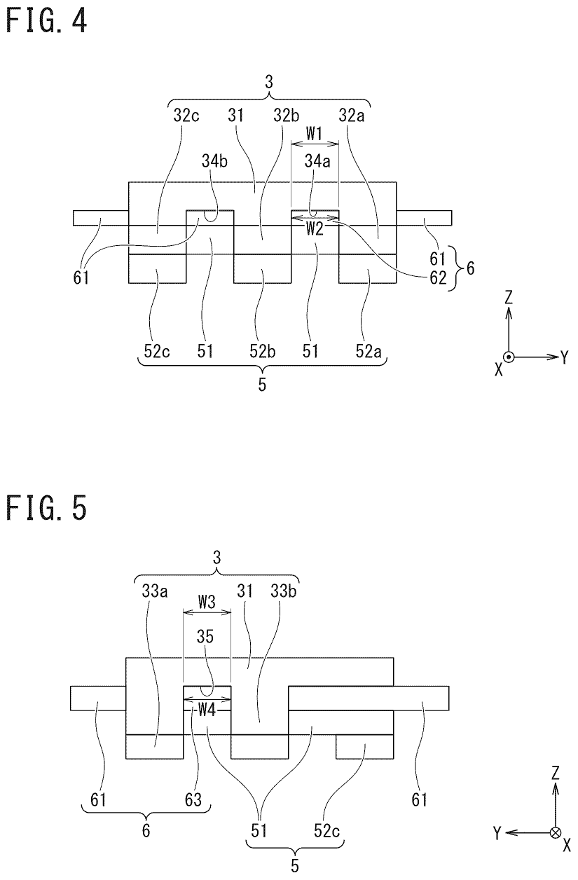

The explanations are further made below while particularly focusing on the terminals 3 and 5 and the insulating layer 6 that are the constituent elements in the semiconductor device according to the first embodiment. FIG. 2 is a plan view illustrating the terminal 3 and the insulating layer 6 that are the constituent elements in the semiconductor device according to the first embodiment. FIG. 3A is a cross-sectional view illustrating the terminals 3 and 5 and the insulating layer 6 taken along line A-A′ in FIG. 2. FIG. 3B is a cross-sectional view illustrating the terminals 3 and 5 and the insulating layer 6 taken along line B-B′ in FIG. 2. FIG. 4 is a cross-sectional view illustrating the terminals 3 and 5 and the insulating layer 6 as viewed in the negative direction of the X-axis. FIG. 5 is a cross-sectional view illustrating the terminals 3 and 5 and the insulating layer 6 as viewed in the positive direction of the X-axis.

FIG. 2 to FIG. 5 partly illustrate, for reasons of expediency, the terminal 3 illustrated in FIG. 1 between one end bonded to the semiconductor chip 2a and the part bonded to the conductive plate 12c, while omitting the illustration of the part on the other end of the terminal 3 projecting from the sealing resin 8. The member from the one end of the terminal 3 bonded to the semiconductor chip 2a to the part bonded to the conductive plate 12c may be different from the member projecting from the sealing resin 8 to serve as an external connection terminal so that the respective members are electrically connected to each other.

As illustrated in FIG. 2 to FIG. 5, the terminal 3 includes a flat part 31, connection parts 32a to 32c bent downward from the flat part 31 so as to be connected to each other, and connection parts 33a and 33b bent downward from the flat part 31 so as to be connected to each other on the opposite side of the connection parts 32a to 32c.

The semiconductor device according to the first embodiment is illustrated with the case in which the flat part 31 has a substantially rectangular planar shape, but is not limited to this case. A part of the bottom surface of the flat part 31 is opposed to the top surface of the terminal 5 with the insulating layer 6 interposed.

The connection parts 32a to 32c are arranged separately from each other in the Y-axis direction and extend parallel to each other in the X-axis direction. The respective bottom surface sides of the connection parts 32b and 32c may be bonded to semiconductor chips (not illustrated) in the same manner as the bottom surface side of the connection part 32a bonded to the semiconductor chip 2a illustrated in FIG. 1. An opening 34a is provided between the respective connection parts 32a and 32b on the lower side of the flat part 31. An opening 34b is provided between the respective connection parts 32b and 32c on the lower side of the flat part 31. The openings 34a and 34b each have a width W1. The semiconductor device according to the first embodiment is illustrated with the case of including the three connection parts 32a to 32c, but may include only two connection parts (for example, the connection parts 32a and 32b) or four or more of the connection parts.

The connection parts 33a and 33b are located at positions opposed to the connection parts 32a and 32b with the flat part 31 interposed. The connection parts 33a and 33b are arranged separately from each other in the Y-axis direction and extend parallel to each other in the X-axis direction. The respective bottom surface sides of the connection parts 33a and 33b are bonded to the conductive plate 12c illustrated in FIG. 1. An opening 35 is provided between the respective connection parts 33a and 33b on the lower side of the flat part 31. The opening 35 has a width W3. The semiconductor device according to the first embodiment is illustrated with the case of including the two connection parts 33a and 33b, but may include three or more connection parts.

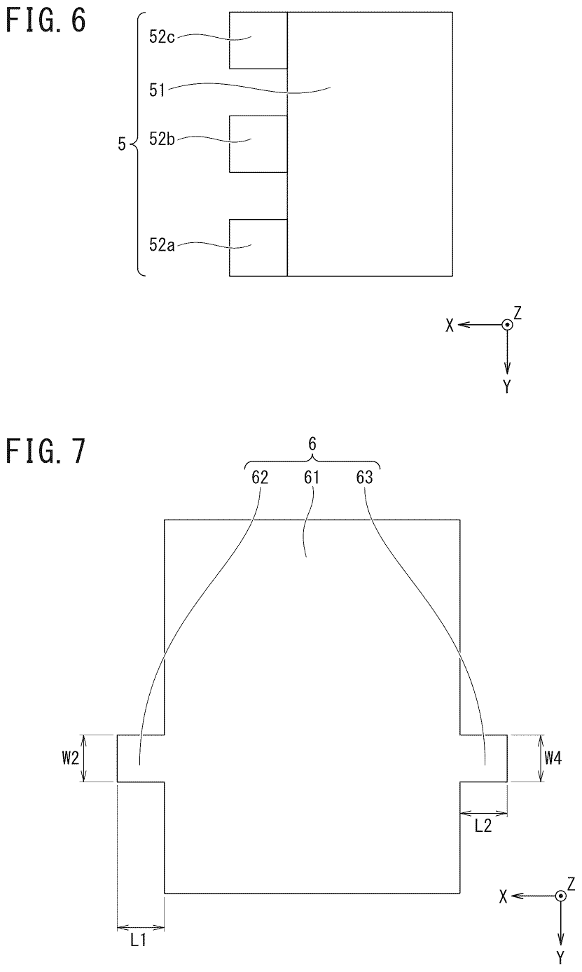

FIG. 6 is a plan view illustrating the terminal 5. As illustrated in FIG. 3A to FIG. 6, the terminal 5 includes a flat part 51, and connection parts 52a to 52c bent downward from the flat part 51 so as to be connected to each other. The semiconductor device according to the first embodiment is illustrated with the case in which the flat part 51 has a substantially rectangular planar shape, but is not limited to this case. As illustrated in FIG. 2 to FIG. 5, the top surface of the flat part 51 is opposed to the bottom surface of the flat part 31 of the terminal 3 with the insulating layer 6 interposed. The bottom surface of the flat part 51 is bonded to the semiconductor chip 2b illustrated in FIG. 1. A plurality of semiconductor chips common to the semiconductor chip 2b may be bonded to the bottom surface of the flat part 51.

The connection parts 52a to 52c are arranged separately from each other in the Y-axis direction and extend parallel to each other in the X-axis direction. The insulating layer 6 is located over the respective connection parts 52a to 52c. The respective bottom surfaces of the connection parts 52a to 52c are bonded to the conductive plate 12a illustrated in FIG. 1. The semiconductor device according to the first embodiment is illustrated with the case of including the three connection parts 52a to 52c, but may include only one connection part (for example, the connection part 52a), may include two connection parts (for example, the connection parts 52a and 52b), or may include four or more connection parts.

FIG. 7 is a plan view illustrating the insulating layer 6. As illustrated in FIG. 2 to FIG. 7, the insulating layer 6 includes a body part 61, a protrusion 62 connected to the body part 61, and a protrusion 63 connected to the body part 61 on the opposite side of the protrusion 62. The insulating layer 6 as used herein is only required to include at least either the protrusion 62 or the protrusion 63, and does not necessarily include both the protrusion 62 and the protrusion 63.

The semiconductor device according to the first embodiment is illustrated with the case in which the body part 61 has a substantially rectangular planar shape, but is not limited to this case. As illustrated in FIG. 2 to FIG. 5, the body part 61 is interposed between the top surface of the flat part 51 of the terminal 5 and the bottom surface of the flat part 31 of the terminal 3. The planar shape of the body part 61 has a size greater than that of each of the flat part 51 of the terminal 5 and the flat part 31 of the terminal 3. The arrangement of the body part 61 can ensure the creepage distance between the terminal 5 and the terminal 3. While FIG. 3A illustrates the case in which both ends of the body part 61 in the X-axis direction are in contact with the connection parts 32a and 33a of the terminal 3, either both or one of the ends of the body part 61 in the X-axis direction may be separated from the connection parts 32a and 33a of the terminal 3.

As illustrated in FIG. 7, the protrusion 62 of the insulating layer 6 is located at a position opposed to the protrusion 63 with the body part 61 interposed. The protrusion 62 has a length L1 in the X-axis direction and a width W2 in the Y-axis direction. The protrusion 63 has a length L2 in the X-axis direction and a width W4 in the Y-axis direction. The length L1 of the protrusion 62 may be either common to or different from the length L2 of the protrusion 63. The width W2 of the protrusion 62 may be either common to or different from the width W4 of the protrusion 63.

As illustrated in FIG. 2, FIG. 3B, and FIG. 4, the protrusion 62 is inserted to the opening 34a of the terminal 3. The insertion of the protrusion 62 in the opening 34a of the terminal 3 fixes the insulating layer 6 to the terminal 3, so as to avoid or reduce a possibility of displacement between the terminal 3 and the insulating layer 6. When the length L1 of the protrusion 62 is greater than or equal to the thickness T1 of the terminal 3, the separation of the insulating layer 6 from the terminal 3 can be avoided effectively. Setting the length L1 of the protrusion 62 to be greater than the thickness T1 of the terminal 3 can lead the tip of the protrusion 62 to be bent so as to avoid the separation of the insulating layer 6 from the terminal 3 more reliably. The length L1 of the protrusion 62 may be less than the thickness T1 of the terminal 3 so that the protrusion 62 is inserted into a part of the opening 34a. The semiconductor device according to the first embodiment is illustrated with the case in which the length L1 of the protrusion 62 is greater than the thickness T1 of the terminal 3 so that the protrusion 62 further projects to the outside of the terminal 3 through the opening 34a.

As illustrated in FIG. 4, the width W2 of the protrusion 62 is set to be smaller than or equal to the width W1 of the opening 34a so as to be inserted to the opening 34a. While the semiconductor device according to the first embodiment is illustrated with the case in which the width W2 of the protrusion 62 is common to the width W1 of the opening 34a, the width W2 of the protrusion 62 may be narrower than the width W1 of the opening 34a.

As illustrated in FIG. 2, FIG. 3B, and FIG. 5, the protrusion 63 is inserted to the opening 35 of the terminal 3. The insertion of the protrusion 63 in the opening 35 of the terminal 3 fixes the insulating layer 6 to the terminal 3, so as to avoid or reduce a possibility of displacement between the terminal 3 and the insulating layer 6. When the length L2 of the protrusion 63 is greater than or equal to the thickness T1 of the terminal 3, the separation of the insulating layer 6 from the terminal 3 can be avoided effectively. Setting the length L2 of the protrusion 63 to be greater than the thickness T1 of the terminal 3 can lead the tip of the protrusion 63 to be bent so as to avoid the separation of the insulating layer 6 from the terminal 3 more reliably. The length L2 of the protrusion 63 may be less than the thickness T1 of the terminal 3 so that the protrusion 63 is inserted into a part of the opening 35. The semiconductor device according to the first embodiment is illustrated with the case in which the length L2 of the protrusion 63 is greater than the thickness T1 of the terminal 3 so that the protrusion 63 further projects to the outside of the terminal 3 through the opening 35.

As illustrated in FIG. 5, the width W4 of the protrusion 63 is set to be smaller than or equal to the width W3 of the opening 35 so as to be inserted to the opening 35. While the semiconductor device according to the first embodiment is illustrated with the case in which the width W4 of the protrusion 63 is common to the width W3 of the opening 35, the width W4 of the protrusion 63 may be narrower than the width W3 of the opening 35.

### Method of Manufacturing Semiconductor Device

An example of a method of manufacturing (assembling) the semiconductor device according to the first embodiment is described below. The semiconductor chips 2a and 2b and the terminals 3 to 5 and 7 are bonded onto the top surface side of the insulated circuit substrate 1 illustrated in FIG. 1 via bonding material such as solder and sintering material. At this point, the insulating layer 6 is interposed between the terminal 3 and the terminal 5 so that the terminal 3 and the terminal 5 are laminated together, and the protrusions 62 and 63 of the insulating layer 6 are respectively inserted to the openings 34a and 35 of the terminal 3 so as to make positioning. Next, the insulated circuit substrate 1, the semiconductor chips 2a and 2b, and the terminals 3 to 5 and 7 are electrically connected as necessary via bonding wires or the like (not illustrated). Thereafter, the insulated circuit substrate 1 and the semiconductor chips 2a and 2b are sealed with the sealing resin 8 by transfer molding, for example. The semiconductor device according to the first embodiment is thus completed through the process as described above.

### Effects

When primary molding is executed in conventional power semiconductor modules with a gap provided between different-electrode terminals, voids can be easily caused in resin between the terminals if the gap is decreased, which would lead to partial discharge as a result of the cause of voids. In addition, when the primary molding is executed in conventional power semiconductor modules with an insulating layer provided between the different-electrode terminals, a creepage distance would not be sufficiently ensured because of displacement between the terminals and the insulating layer, which cannot decrease the gap between the terminals or cannot achieve a reduction in inductance sufficiently. Further, when the insulating layer is fixed between the different-electrode terminals with positioning pins used in conventional power semiconductor modules, the creepage distance between the different electrodes would not be sufficiently ensured if gaps are caused between the positioning pins and holes because of thermal stress during thermal cycles, resulting in a cause of discharge. The configurations of such conventional power semiconductor modules thus cannot contribute to both a reduction in inductance and insulation reliability.

As compared with such conventional power semiconductor modules, the semiconductor device according to the first embodiment has the configuration in which the protrusion 62 of the insulating layer 6 is inserted to the opening 34a of the terminal 3, and the protrusion 63 of the insulating layer 6 is inserted to the opening 35 of the terminal 3 during the assembly of the semiconductor device. This configuration can lead the insulating layer 6 to be fixed to the terminal 3 and facilitate the positioning between the terminal 3 and the insulating layer 6, so as to ensure the insulation properties between the respective terminals 3 and 5. Setting the size of the body part 61 of the insulating layer 6 to be greater than the opposed part between the flat part 31 of the termina 3 and the flat part 51 of the terminal 5 in the planar view can reliably ensure the insulation properties regardless of whether the thickness of the insulating layer 6 is decreased, so as to achieve both the reduction in inductance and the insulation reliability.

### EXAMPLES

An example of the semiconductor device according to the first embodiment is described below in comparison with a first comparative example and a second comparative example. The semiconductor device of the example according to the first embodiment was manufactured such that semiconductor chips (rated voltage of 1200 V) were bonded onto an insulated circuit substrate by soldering, and different-electrode terminals and the like were further bonded, followed by sealing with resin. The semiconductor device of the example according to the first embodiment used an insulating sheet as an insulating layer between the terminals, set a distance between the terminals to 0.38 millimeters, and set an inductance ratio between the terminals to 0.79. The term “inductance ratio” as used herein refers to a ratio in which the distance between the terminals corresponding to one millimeter is defined as one.

A semiconductor device of the first comparative example was manufactured by primary molding in a state in which an insulating layer was interposed between different-electrode terminals. The first comparative example used polyphenylene sulfide (PPS) for the insulating layer between the terminals, set the distance between the terminals to 1.5 millimeters, and set the inductance ratio between the terminals to one. The other manufacturing conditions in the first comparative example were the same as those in the semiconductor device of the example according to the first embodiment.

A semiconductor device of the second comparative example was manufactured such that an insulating layer was fixed between different-electrode terminals with positioning pins used. The second comparative example used an insulating sheet as the insulating layer between the terminals, set the distance between the terminals to 0.38 millimeters, and set the inductance ratio between the terminals to 0.79. The other manufacturing conditions in the second comparative example were the same as those in the semiconductor device of the example according to the first embodiment.

A partial discharge evaluation was executed after thermal cycles for the respective semiconductor devices of the example according to the first embodiment, the first comparative example, and the second comparative example manufactured as described above. The thermal cycles were executed under the conditions in which a reciprocation process at temperature between −40° C. and 125° C. was set as one cycle, and a partial discharge was evaluated every 500 cycles. The partial discharge evaluation was made such that a voltage was gradually applied until reaching 2.5 kV, and a state with no partial discharge was determined when a discharge amount after 60 seconds was 1 pC or less.

The first comparative example, in which no partial discharge appeared even at 2000 cycles, had no problem with the insulation properties after the thermal cycles. However, the first comparative example could not reduce the inductance of the module but caused a large switching loss. The second comparative example, in which partial discharge appeared at 500 cycles, could not provide a permissible module with high reliability because of a problem with the insulation properties after the thermal cycles. In contrast, the semiconductor device of the example according to the first embodiment did not have any problem with the insulation properties after the thermal cycles because no partial discharge appeared even at 2000 cycles, so as to reduce the inductance, achieving a reduction in switching loss, accordingly.

### Second Embodiment

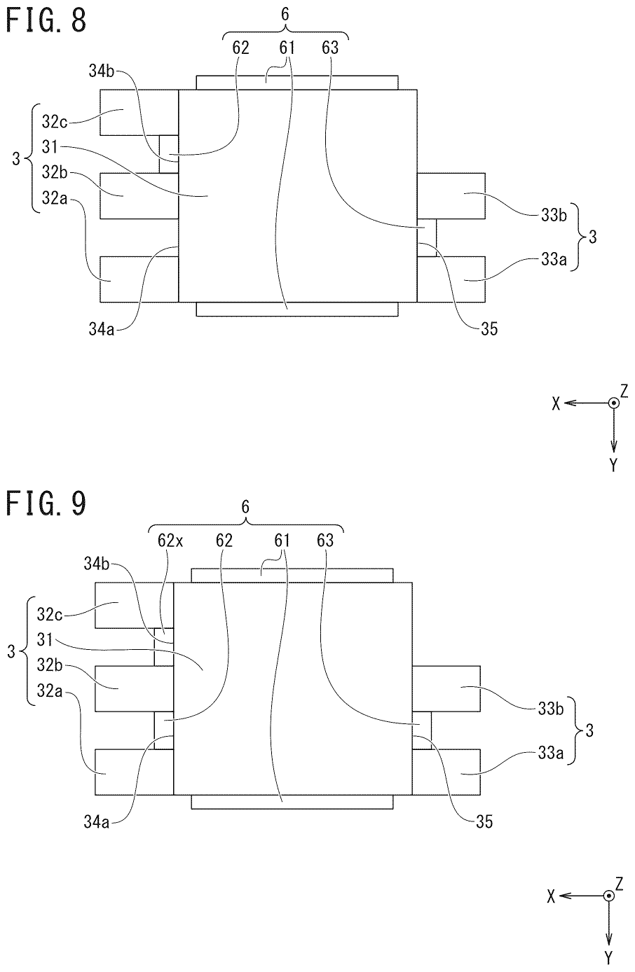

FIG. 8 is a plan view illustrating the terminal 3 and the insulating layer 6 that are constituent elements included in a semiconductor device according to a second embodiment. As illustrated in FIG. 8, the semiconductor device according to the second embodiment differs from the semiconductor device according to the first embodiment illustrated in FIG. 2 in that the position of the protrusion 62 of the insulating layer 6 is shifted so as not to be opposed to the protrusion 63 with the body part 61 interposed. The protrusion 62 is inserted to the opening 34b provided between the connection parts 32b and 32c of the terminal 3. The other configurations of the semiconductor device according to the second embodiment are substantially the same as those of the semiconductor device according to the first embodiment, and overlapping explanations are not repeated below.

The semiconductor device according to the second embodiment may have the configuration in which the position of the protrusion 62 of the insulating layer 6 is shifted so as not to be opposed to the protrusion 63 with the body part 61 interposed. This configuration leads the protrusion 62 of the insulating layer 6 to be inserted to the opening 34b of the terminal 3 and leads the protrusion 63 of the insulating layer 6 to be inserted to the opening 35 of the terminal 3, so as to fix the insulating layer 6 to the terminal 3 and thus facilitate the positioning between the terminal 3 and the insulating layer 6, ensuring the insulation properties between the respective terminals 3 and 5 accordingly. Further, the configuration in which the protrusion 62 of the insulating layer 6 is not opposed to but displaced from the protrusion 63 with the body part 61 interposed so as to be inserted to the opening 34b of the terminal 3, can avoid the displacement between the terminal 3 and the insulating layer 6 more reliably.

### Third Embodiment

FIG. 9 is a plan view illustrating the terminal 3 and the insulating layer 6 that are constituent elements included in a semiconductor device according to a third embodiment. As illustrated in FIG. 9, the semiconductor device according to the third embodiment differs from the semiconductor device according to the first embodiment illustrated in FIG. 2 in further including a protrusion 62x provided parallel to the protrusion 62 in the insulating layer 6. The protrusion 62x is inserted to the opening 34b provided between the respective connection parts 32b and 32c of the terminal 3. The other configurations of the semiconductor device according to the third embodiment are substantially the same as those of the semiconductor device according to the first embodiment, and overlapping explanations are not repeated below.

The semiconductor device according to the third embodiment may have the configuration in which the protrusion 62x is further provided parallel to the protrusion 62 in the insulating layer 6. This configuration leads the protrusions 62 and 62x to be inserted respectively to the openings 34a and 34b of the terminal 3 and leads the protrusion 63 to be inserted to the opening 35 of the terminal 3, so as to fix the insulating layer 6 to the terminal 3 and thus facilitate the positioning between the terminal 3 and the insulating layer 6, ensuring the insulation properties between the terminals 3 and 5 accordingly. Further, the provision of the protrusion 62x parallel to the protrusion 62 in the insulating layer 6 to be inserted to the opening 34b of the terminal 3 can avoid the displacement between the terminal 3 and the insulating layer 6 more reliably.

### Fourth Embodiment

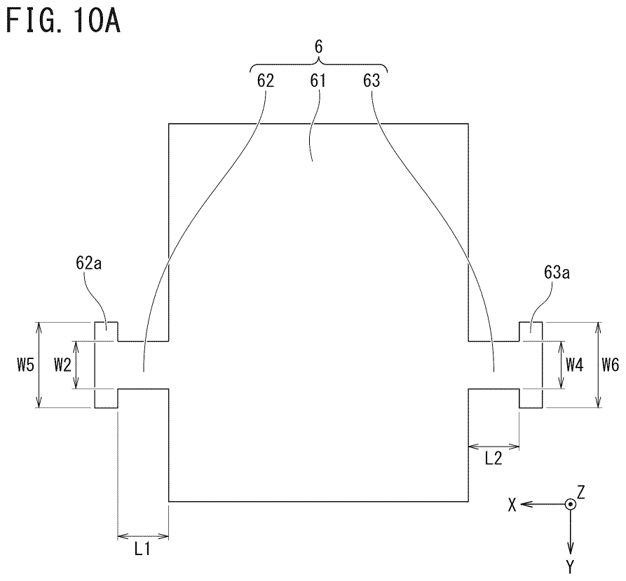

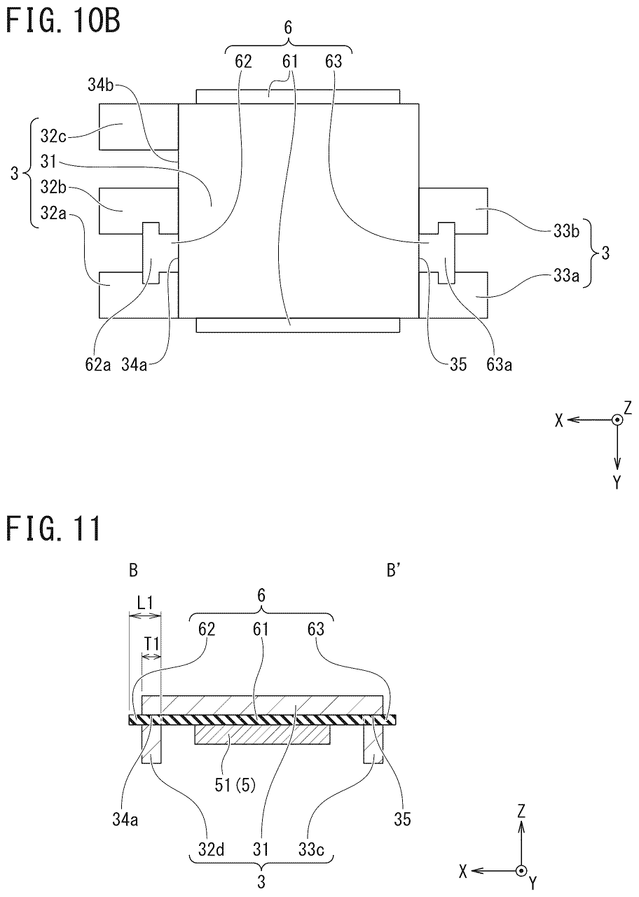

FIG. 10A is a plan view illustrating the insulating layer 6 that is a constituent element included in a semiconductor device according to a fourth embodiment. As illustrated in FIG. 10A, the semiconductor device according to the fourth embodiment differs from the semiconductor device according to the first embodiment illustrated in FIG. 7 in that the protrusions 62 and 63 of the insulating layer 6 are respectively provided with catch parts 62a and 63a. A width W5 of the catch part 62a is greater than the width W2 of the protrusion 62. A width W6 of the catch part 63a is greater than the width W4 of the protrusion 63. The insulating layer 6 may be provided with either the catch part 62a or 63a in the protrusion 62 or 63.

FIG. 10B is a plan view illustrating the terminal 3 and the insulating layer 6 that are the constituent elements included in the semiconductor device according to the fourth embodiment. As illustrated in FIG. 10B, the protrusion 62 of the insulating layer 6 is inserted to the opening 34a of the terminal 3. The catch part 62a at the tip of the protrusion 62 is located on the outside of the outer edge of the flat part 31 of the terminal 3. The protrusion 63 of the insulating layer 6 is inserted to the opening 35 of the terminal 3. The catch part 63a at the tip of the protrusion 63 is located on the outside of the outer edge of the flat part 31 of the terminal 3. The other configurations of the semiconductor device according to the fourth embodiment are substantially the same as those of the semiconductor device according to the first embodiment, and overlapping explanations are not repeated below.

The semiconductor device according to the fourth embodiment may have the configuration in which the protrusions 62 and 63 of the insulating layer 6 are respectively provided with the catch parts 62a and 63a. This configuration leads the protrusion 62 to be inserted to the opening 34a of the terminal 3 and leads the protrusion 63 to be inserted to the opening 35 of the terminal 3, so as to fix the insulating layer 6 to the terminal 3 and thus facilitate the positioning between the terminal 3 and the insulating layer 6, ensuring the insulation properties between the terminals 3 and 5 accordingly. Further, the provision of the catch parts 62a and 63a in the protrusions 62 and 63 of the insulating layer 6 can prevent the insulating layer 6 from being separated from the terminal 3 more reliably.

### Fifth Embodiment

FIG. 11 is a cross-sectional view illustrating the terminals 3 and 5 and the insulating layer 6 that are constituent elements included in a semiconductor device according to a fifth embodiment, corresponding to the cross section of the semiconductor device according to the first embodiment illustrated in FIG. 3B. As illustrated in FIG. 11, the semiconductor device according to the fifth embodiment differs from the semiconductor device according to the first embodiment illustrated in FIG. 3B in that the lower side of the respective openings 34a and 35 provided in the terminal 3 is closed. A side-wall part 32d is provided on the lower side of the opening 34a. The side-wall part 32d is connected between the respective connection parts 32a and 32b illustrated in FIG. 2. A side-wall part 33c is provided on the lower side of the opening 35. The side-wall part 33c is connected between the respective connection parts 33a and 33b illustrated in FIG. 2. The other configurations of the semiconductor device according to the fifth embodiment are substantially the same as those of the semiconductor device according to the first embodiment, and overlapping explanations are not repeated below.

The semiconductor device according to the fifth embodiment may have the configuration in which the lower side of the respective openings 34a and 35 provided in the terminal 3 is closed. This configuration also leads the protrusion 62 to be inserted to the opening 34a of the terminal 3 and leads the protrusion 63 to be inserted to the opening 35 of the terminal 3, so as to fix the insulating layer 6 to the terminal 3 and thus facilitate the positioning between the terminal 3 and the insulating layer 6, ensuring the insulation properties between the terminals 3 and 5 accordingly.

### Sixth Embodiment

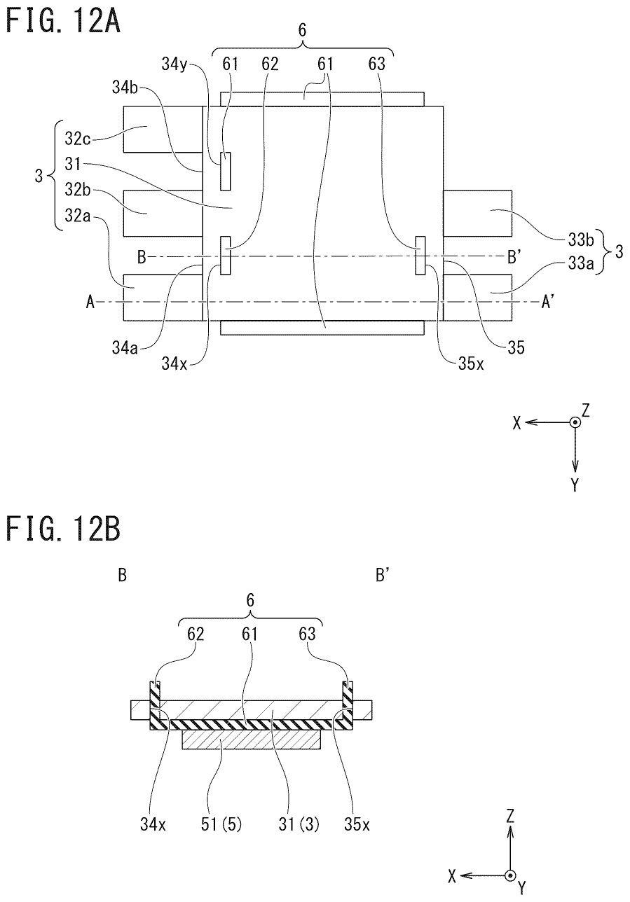

FIG. 12A is a cross-sectional view illustrating the terminal 3 and the insulating layer 6 that are constituent elements included in a semiconductor device according to a sixth embodiment. The cross section of the terminals 3 and 5 and the insulating layer 6 taken along line A-A′ in FIG. 12A is common to FIG. 3A. FIG. 12B is a cross-sectional view illustrating the respective terminals 3 and 5 and the insulating layer 6 taken along line B-B′ in FIG. 12A. As illustrated in FIG. 12A and FIG. 12B, the semiconductor device according to the sixth embodiment differs from the semiconductor device according to the first embodiment illustrated in FIG. 2 and FIG. 3B in that the flat part 31 of the terminal 3 is provided with openings 34x, 34y, and 35x penetrating in the Z-axis direction.

The flat part 31 of the terminal 3 is partly opposed to the flat part 51 of the terminal 5 with the body part 61 of the insulating layer 6 interposed. The openings 34x, 34y, and 35x are provided in the flat part 31 of the terminal 3 in the other areas not opposed to the flat part 51 of the terminal 5. The protrusion 62 of the insulating layer 6 is bent upward to make a right angle with the body part 61 so as to be inserted to the opening 34x. The protrusion 63 of the insulating layer 6 is bent upward to make a right angle with the body part 61 so as to be inserted to the opening 35x.

The opening 34y to which the protrusion 62 of the insulating layer 6 is not inserted is not necessarily provided in the terminal 3. The protrusion 62 of the insulating layer 6 may be shifted to a position not opposed to the protrusion 63 with the body part 61 interposed so as to be inserted to the opening 34y instead. The other configurations of the semiconductor device according to the sixth embodiment are substantially the same as those of the semiconductor device according to the first embodiment, and overlapping explanations are not repeated below.

The semiconductor device according to the sixth embodiment may have the configuration in which the flat part 31 of the terminal 3 is provided with the openings 34x and 35x penetrating in the Z-axis direction, and the protrusions 62 and 63 of the insulating layer 6 are bent so as to be inserted to the openings 34x and 35x respectively. This configuration can also fix the insulating layer 6 to the terminal 3 and thus facilitate the positioning between the terminal 3 and the insulating layer 6, so as to ensure the insulation properties between the terminals 3 and 5. Further, the configuration in which the protrusions 62 and 63 of the insulating layer 6 are bent so as to be inserted to the openings 34x and 35x can avoid a displacement between the terminal 3 and the insulating layer 6 in the X-axis direction and the Y-axis direction more reliably.

### Seventh Embodiment

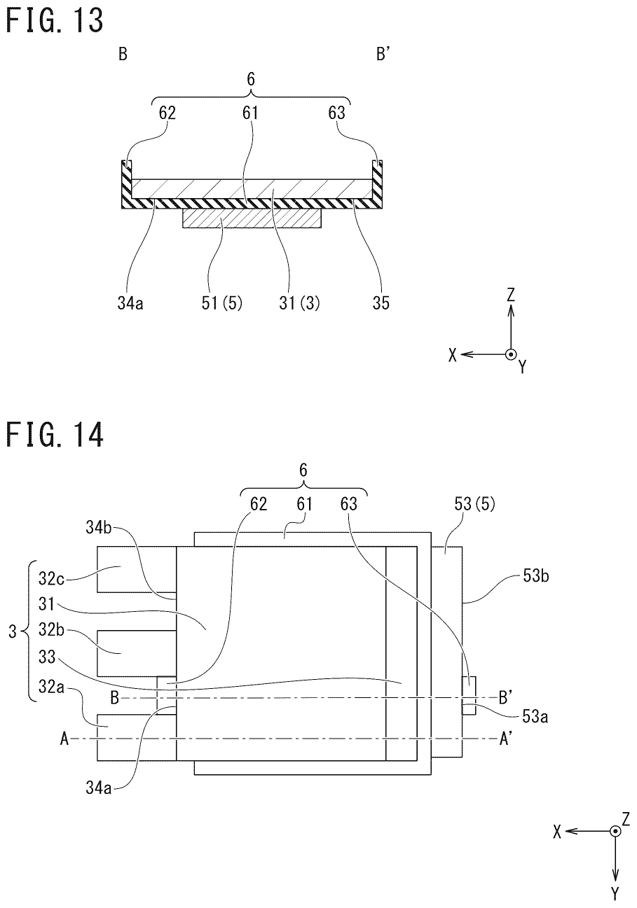

FIG. 13 is a cross-sectional view illustrating the terminals 3 and 5 and the insulating layer 6 that are constituent elements included in a semiconductor device according to a seventh embodiment, corresponding to the cross section of the semiconductor device according to the first embodiment illustrated in FIG. 3B. As illustrated in FIG. 13, the semiconductor device according to the seventh embodiment differs from the semiconductor device according to the first embodiment illustrated in FIG. 3B in that the projecting tip parts of the protrusions 62 and 63 of the insulating layer 6 inserted to the openings 34a and 35 are bent up. Only one of tip parts of the protrusions 62 and 63 of the insulating layer 6 may be bent up. The other configurations of the semiconductor device according to the seventh embodiment are substantially the same as those of the semiconductor device according to the first embodiment, and overlapping explanations are not repeated below.

The semiconductor device according to the seventh embodiment may have the configuration in which the projecting tip parts of the protrusions 62 and 63 of the insulating layer 6 inserted to the openings 34a and 35 are bent up. This configuration also leads the protrusion 62 to be inserted to the opening 34a of the terminal 3 and leads the protrusion 63 to be inserted to the opening 35 of the terminal 3, so as to fix the insulating layer 6 to the terminal 3 and thus facilitate the positioning between the terminal 3 and the insulating layer 6, ensuring the insulation properties between the terminals 3 and 5 accordingly. Further, providing the protrusions 62 and 63 of the insulating layer 6 with the bent tip parts can prevent the insulating layer 6 from being separated from the terminal 3 more reliably.

### Eighth Embodiment

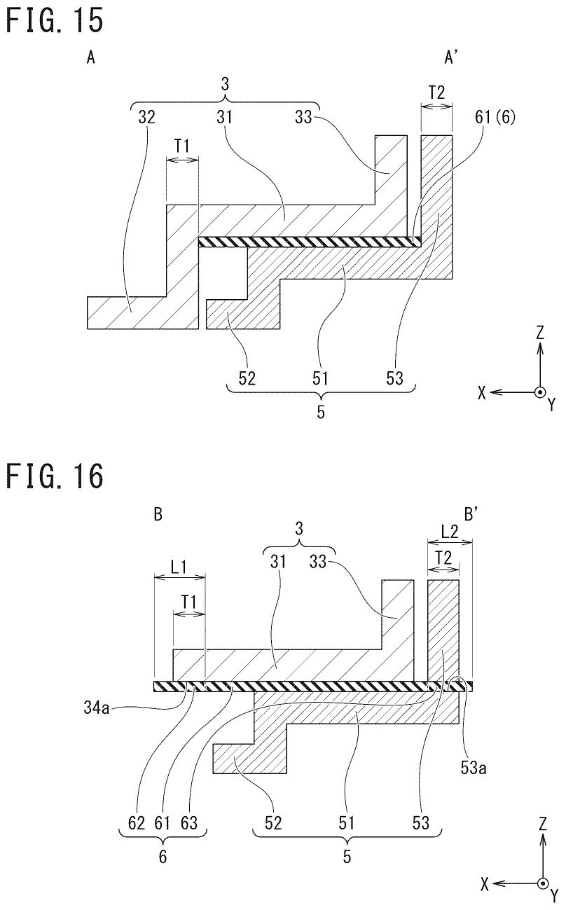

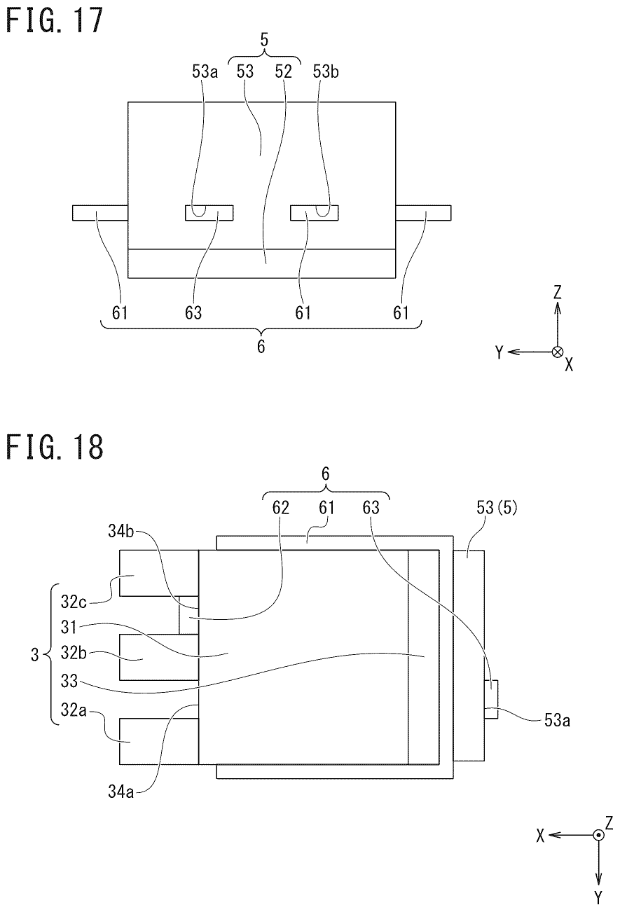

FIG. 14 is a plan view illustrating the terminal 3 and the insulating layer 6 that are constituent elements included in a semiconductor device according to an eighth embodiment. FIG. 15 is a cross-sectional view illustrating the respective terminals 3 and 5 and the insulating layer 6 taken along line A-A′ in FIG. 14. FIG. 16 is a cross-sectional view illustrating the respective terminals 3 and 5 and the insulating layer 6 taken along line B-B′ in FIG. 14. FIG. 17 is a side view illustrating the respective terminals 3 and 5 and the insulating layer 6 as viewed in the positive direction of the X axis.

As illustrated in FIG. 14 to FIG. 17, the semiconductor device according to the eighth embodiment differs from the semiconductor device according to the first embodiment illustrated in FIG. 2 to FIG. 5 in that the protrusion 62 of the insulating layer 6 is inserted to the opening 34a of the terminal 3 that is one of the terminals, and the protrusion 63 of the insulating layer 6 is inserted to an opening 53a of the other terminal 5.

The respective terminals 3 and 5 are arranged on the top surface side of the insulated circuit substrate 1 illustrated in FIG. 1 and are electrically connected to the respective semiconductor chips 2a and 2b. The arranged position, the length, the width, and the thickness of the respective terminals 3 and 5 can be determined as appropriate. The positions and the number of the bent parts provided in the respective terminals 3 and 5 can also be determined as appropriate. One of the terminals 3 and 5 may serve as a positive-electrode terminal which is an external connection terminal, and the other one of the terminals 3 and 5 may serve as a negative-electrode terminal which is an external connection terminal. The respective terminals 3 and 5 are arranged adjacent to each other (laminated together) so as to be opposed to each other with the insulating layer 6 interposed. The terminals 3 and 5 are different-electrode terminals to which different potentials are applied, and currents flow through the respective terminals 3 and 5 in the opposite directions.

The terminal 3 includes the flat part 31, the connection parts 32a to 32c bent downward from the flat part 31 so as to be connected to each other, and a connection part 33 bent upward from the flat part 31 so as to be connected to each other on the opposite side of the connection parts 32a to 32c. The respective shapes of the flat part 31 and the connection parts 32a to 32c are common to those of the flat part 31 and the connection parts 32a to 32c illustrated in FIG. 2 to FIG. 5. The opening 34a is provided between the respective connection parts 32a and 32b on the lower side of the flat part 31. The opening 34b is provided between the respective connection parts 32b and 32c on the lower side of the flat part 31.

The connection part 33 is arranged to extend in the Z-axis direction. The connection part 33 is not provided with any opening. The upper end of the connection part 33 may project upward from the top surface of the sealing resin 8 (refer to FIG. 1).

The terminal 5 includes the flat part 51, a connection part 52 bent downward from the flat part 51 so as to be connected to each other, and a connection part 53 bent upward from the flat part 51 so as to be connected to each other on the opposite side of the connection part 52. The shape of the flat part 51 is common to that of the flat part 51 illustrated in FIG. 2 to FIG. 5. The flat part 51 is arranged to be opposed to a part of the flat part 31 of the terminal 3 with the insulating layer 6 interposed. The connection part 52 may be divided into three parts, as in the case of the connection parts 52a to 52c illustrated in FIG. 2 to FIG. 5.

The connection part 53 is arranged to extend parallel to the connection part 33 of the terminal 3 in the Z-axis direction. As illustrated in FIG. 14, FIG. 16, and FIG. 17, the connection part 53 is provided with openings 53a and 53b penetrating in the X-axis direction. The provision of the opening 53b is optional. The upper end of the connection part 53 may project upward from the top surface of the sealing resin 8 (refer to FIG. 1).

The shape of the insulating layer 6 is common to that of the insulating layer 6 illustrated in FIG. 7. The insulating layer 6 includes the body part 61, the protrusion 62 connected to the body part 61, and the protrusion 63 connected to the body part 61 on the opposite side of the protrusion 62. The protrusion 62 of the insulating layer 6 is inserted to the opening 34a of the terminal 3. The protrusion 63 of the insulating layer 6 is inserted to the opening 53a of the terminal 5.

The relation between the length L1 of the protrusion 62 and the thickness T1 of the terminal 3 is common to that in the semiconductor device according to the first embodiment. When the length L2 of the protrusion 63 is greater than or equal to the thickness T2 of the terminal 5, the separation of the insulating layer 6 from the terminal 5 can be avoided effectively. Setting the length L2 of the protrusion 63 to be greater than the thickness T2 of the terminal 5 can lead the tip of the protrusion 63 to be bent so as to avoid the separation of the insulating layer 6 from the terminal 5 more reliably. The length L2 of the protrusion 63 may be less than the thickness T2 of the terminal 5 so that the protrusion 63 is inserted into a part of the opening 53a. The other configurations of the semiconductor device according to the eighth embodiment are substantially the same as those of the semiconductor device according to the first embodiment, and overlapping explanations are not repeated below.

The semiconductor device according to the eighth embodiment may have the configuration in which the protrusion 62 of the insulating layer 6 is inserted to the opening 34a of the terminal 3 that is one of the terminals, and the protrusion 63 of the insulating layer 6 is inserted to the opening 53a of the other terminal 5. This configuration can fix the insulating layer 6 to both of the terminals 3 and 5 and thus facilitate the positioning between the insulating layer 6 and the respective terminals 3 and 5, so as to ensure the insulation properties between the terminals 3 and 5.

### Ninth Embodiment

FIG. 18 is a plan view illustrating the terminals 3 and 5 and the insulating layer 6 that are constituent elements included in a semiconductor device according to a ninth embodiment. As illustrated in FIG. 18, the semiconductor device according to the ninth embodiment differs from the semiconductor device according to the eighth embodiment illustrated in FIG. 14 in that the position of the protrusion 62 of the insulating layer 6 is shifted so as not to be opposed to the protrusion 63 with the body part 61 interposed. The protrusion 62 is inserted to the opening 34b provided between the connection parts 32b and 32c of the terminal 3. The other configurations of the semiconductor device according to the ninth embodiment are substantially the same as those of the semiconductor device according to the eighth embodiment, and overlapping explanations are not repeated below.

The semiconductor device according to the ninth embodiment may have the configuration in which the position of the protrusion 62 of the insulating layer 6 is shifted so as not be opposed to the protrusion 63 with the body part 61 interposed. This configuration leads the protrusion 62 of the insulating layer 6 to be inserted to the opening 34b of the terminal 3 and leads the protrusion 63 of the insulating layer 6 to be inserted to the opening 53a of the terminal 5, so as to fix the insulating layer 6 to both of the terminals 3 and 5 and thus facilitate the positioning between the insulating layer 6 and the respective terminals 3 and 5, ensuring the insulation properties between the respective terminals 3 and 5 accordingly. Further, the arrangement of the protrusion 62 of the insulating layer 6 at a position not opposed to but displaced from the protrusion 63 with the body part 61 interposed so as to be inserted to the opening 34b of the terminal 3, can avoid the displacement between the terminal 3 and the insulating layer 6 more reliably.

### Tenth Embodiment

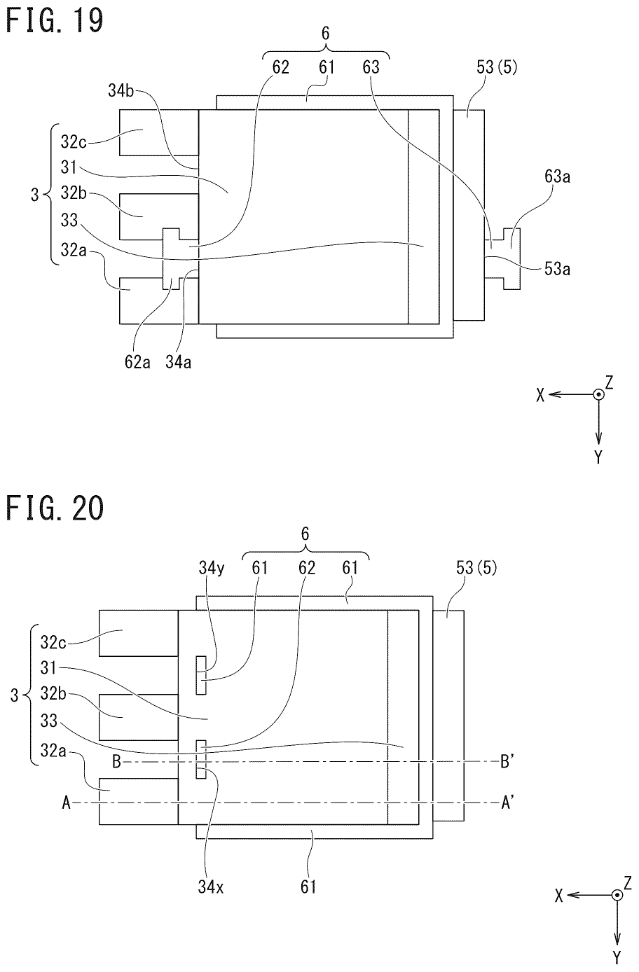

FIG. 19 is a plan view illustrating the terminals 3 and 5 and the insulating layer 6 that are constituent elements included in a semiconductor device according to a tenth embodiment. As illustrated in FIG. 19, the semiconductor device according to the tenth embodiment differs from the semiconductor device according to the eighth embodiment illustrated in FIG. 14 in that the protrusions 62 and 63 of the insulating layer 6 are respectively provided with the catch parts 62a and 63a. The insulating layer 6 may be provided with either the catch part 62a or 63a in the protrusion 62 or 63. The other configurations of the semiconductor device according to the tenth embodiment are substantially the same as those of the semiconductor device according to the eighth embodiment, and overlapping explanations are not repeated below.

The semiconductor device according to the tenth embodiment may have the configuration in which the protrusions 62 and 63 of the insulating layer 6 are respectively provided with the catch parts 62a and 63a. This configuration leads the protrusion 62 of the insulating layer 6 to be inserted to the opening 34a of the terminal 3 and leads the protrusion 63 of the insulating layer 6 to be inserted to the opening 53a of the terminal 5, so as to fix the insulating layer 6 to both of the terminals 3 and 5 and thus facilitate the positioning between the insulating layer 6 and the respective terminals 3 and 5, ensuring the insulation properties between the terminals 3 and 5 accordingly. Further, the provision of the catch parts 62a and 63a in the protrusions 62 and 63 of the insulating layer 6 can prevent the insulating layer 6 from being separated from the terminal 3 more reliably.

### Eleventh Embodiment

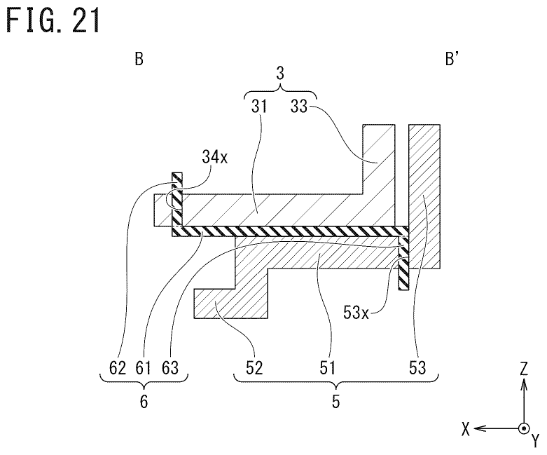

FIG. 20 is a plan view illustrating the terminals 3 and 5 and the insulating layer 6 that are constituent elements included in a semiconductor device according to an eleventh embodiment. The cross section taken along line A-A′ in FIG. 20 is common to FIG. 15. FIG. 21 is a cross-sectional view illustrating the terminals 3 and 5 and the insulating layer 6 taken along line B-B′ in FIG. 20.

As illustrated in FIG. 20 and FIG. 21, the semiconductor device according to the eleventh embodiment differs from the semiconductor device according to the eighth embodiment illustrated in FIG. 14 and FIG. 16 in that the flat part 31 of the terminal 3 is provided with the openings 34x and 34y penetrating in the Z-axis direction at positions not opposed to the terminal 5, and the flat part 51 of the terminal 5 is provided with an opening 53x penetrating in the Z-axis direction at a position not opposed to the terminal 3.

The protrusion 62 of the insulating layer 6 is bent upward to make a right angle with the body part 61 so as to be inserted to the opening 34x. The protrusion 63 of the insulating layer 6 is bent downward to make a right angle with the body part 61 so as to be inserted to the opening 53x. The opening 34y to which the protrusion 62 of the insulating layer 6 is not inserted is not necessarily provided in the terminal 3. The protrusion 62 of the insulating layer 6 may be shifted to a position not opposed to the protrusion 63 with the body part 61 interposed so as to be inserted to the opening 34y instead. The other configurations of the semiconductor device according to the eleventh embodiment are substantially the same as those of the semiconductor device according to the eighth embodiment, and overlapping explanations are not repeated below.

The semiconductor device according to the eleventh embodiment may have the configuration in which the flat part 31 of the terminal 3 is provided with the opening 34x penetrating in the Z-axis direction, the flat part 51 of the terminal 5 is provided with the opening 53x penetrating in the Z-axis direction, and the protrusions 62 and 63 of the insulating layer 6 are bent so as to be inserted to the openings 34x and 53x respectively. This configuration can also fix the insulating layer 6 to the respective terminals 3 and 5 and thus facilitate the positioning between the insulating layer 6 and the respective terminals 3 and 5, so as to ensure the insulation properties between the terminals 3 and 5. Further, the configuration in which the protrusions 62 and 63 of the insulating layer 6 are bent so as to be inserted to the openings 34x and 53x can avoid a displacement between the insulating layer 6 and the respective terminals 3 and 5 in the X-axis direction and the Y-axis direction more reliably.

### Other Embodiments

While the present disclosure has been described above according to the first to eleventh embodiments, it should be understood that the present disclosure is not intended to be limited to the descriptions and the drawings composing part of this disclosure. Various alternative embodiments, examples, and technical applications will be apparent to those skilled in the art according to this disclosure.

For example, the semiconductor device according to the eighth embodiment illustrated in FIG. 14 to FIG. 17 may have a configuration in which the insulating layer 6 is further provided with the protrusion 62x so as to be inserted to the opening 34b, as in the case of the semiconductor device according to the third embodiment illustrated in FIG. 9. The semiconductor device according to the eighth embodiment illustrated in FIG. 14 to FIG. 17 may also have a configuration in which the protrusions 62 and 63 of the insulating layer 6 are provided with bent tip parts, as in the case of the semiconductor device according to the seventh embodiment illustrated in FIG. 13.

In addition, the configurations disclosed in the first to eleventh embodiments can be combined together as appropriate within a range having no contradiction between the embodiments. It should also be understood that the present disclosure can include various embodiments not disclosed herein. The technical scope of the present disclosure is thus defined only by the subject matter according to the appended claims reasonably derived from the foregoing descriptions.

What is claimed is:

1. A semiconductor device comprising:
a first terminal:
a second terminal having a part opposed to the first terminal and another part provided with a first opening not opposed to the first terminal; and
an insulating layer including a body part interposed between the first terminal and the second terminal opposed to each other, and a first protrusion connected to the body part and inserted to the first opening.

2. The semiconductor device of claim 1, wherein
the second terminal includes:
a first flat part having at least a part opposed to the first terminal; and
a first connection part bent from the first flat part so as to be connected to each other.

3. The semiconductor device of claim 2, wherein the first opening is provided in the first connection part.

4. The semiconductor device of claim 2, wherein
a part of the first flat part is opposed to the first terminal, and another part of the first flat part not opposed to the first terminal is provided with the first opening, and
the first protrusion is bent from the body part so as to be inserted to the first opening.

5. The semiconductor device of claim 2, wherein
the second terminal further includes a second connection part bent from the first flat part so as to be connected to each other on an opposite side of the first connection part, and provided with a second opening, and
the insulating layer further includes a second protrusion connected to the body part and inserted to the second opening.

6. The semiconductor device of claim 1, wherein
a part of the first terminal is opposed to the second terminal, and another part of the first terminal not opposed to the second terminal is provided with a second opening, and
the insulating layer further includes a second protrusion connected to the body part and inserted to the second opening.

7. The semiconductor device of claim 6, wherein
the first terminal includes:
a second flat part having at least a part opposed to the second terminal; and
a third connection part bent from the second flat part so as to be connected to each other.

8. The semiconductor device of claim 7, wherein the third connection part is provided with the second opening.

9. The semiconductor device of claim 7, wherein
a part of the second flat part is opposed to the second terminal, and another part of the second flat part is provided with the second opening, and
the second protrusion is bent so as to be inserted to the second opening.

10. The semiconductor device of claim 5, wherein the first protrusion and the second protrusion are located so as to be opposed to each other with the body part interposed.

11. The semiconductor device of claim 5, wherein the first protrusion and the second protrusion are shifted from each other so as not to be opposed to each other with the body part interposed.

12. The semiconductor device of claim 1, wherein the first protrusion is provided with a catch part.

13. The semiconductor device of claim 1, wherein a tip part of the first protrusion projects from the first opening and is further bent.

14. The semiconductor device of claim 1, wherein a length of the first protrusion is greater than or equal to a thickness of the second terminal.

15. The semiconductor device of claim 1, further comprising:
an insulated circuit substrate provided with the first terminal and the second terminal on a top surface side;
a semiconductor chip provided on the top surface side of the insulated circuit substrate and electrically connected to the first terminal and the second terminal; and
a sealing resin provided to seal the insulated circuit substrate and the semiconductor chip.
